(19) United States
(12) Patent Application Publication
(10) Pub. No.: US 2013/0027872 A1
(43) Pub. Date: Jan. 31, 2013

(54) SUPPORTING ASSEMBLY FOR ASSEMBLED DETACHABLE ELECTRONIC DEVICE AND ASSEMBLED DETACHABLE ELECTRONIC DEVICE HAVING THE SAME

(71) Applicants: Chien-I Lin, Taipei City (TW); Hsiao-Ling Chan, Taipei City (TW); Chih-Chien Lin, Taipei City (TW); Ting-Kang Ou, Taipei City (TW); Hsin Lu, Taipei City (TW); Yung-Hsiang Chen, Taipei City (TW)

(72) Inventors: Chien-I Lin, Taipei City (TW); Hsiao-Ling Chan, Taipei City (TW); Chih-Chien Lin, Taipei City (TW); Ting-Kang Ou, Taipei City (TW); Hsin Lu, Taipei City (TW); Yung-Hsiang Chen, Taipei City (TW)

(73) Assignee: COMPAL ELECTRONICS, INC., Taipei City (TW)

(21) Appl. No.: 13/556,160

(22) Filed: Jul. 23, 2012

Related U.S. Application Data
(60) Provisional application No. 61/511,539, filed on Jul. 25, 2011.

(51) Int. Cl. H05K 7/00; G06F 1/16

(52) U.S. Cl. 361/679.41; 361/807

(57) ABSTRACT

An assembled detachable electronic device includes a portable device having a display interface and a docking station is provided. The portable device includes at least one first sliding portion. The docking station includes a docking station main body and a supporting assembly assembled to the docking station main body to support the portable device. The supporting assembly includes a flexible element and a sliding element. The sliding element is wrapped by the flexible element. When the sliding element is slidably disposed to the first sliding portion, the flexible element provides a supporting force to support the portable device on the docking station main body. When the sliding element slides along the first sliding portion and the flexible element is bent, the portable device rotates relative to the docking station main body.

### CROSS-REFERENCE TO RELATED APPLICATION

This application claims the priority benefits of U.S. provisional application Ser. No. 61/511,539, filed on Jul. 25, 2011. The entirety of the above-mentioned patent applications is hereby incorporated by reference herein and made a part of this specification.

### BACKGROUND OF THE INVENTION

1. Field of the Invention

The invention relates to a supporting assembly and an electronic device having the same. More particularly, the invention relates to a supporting assembly for an assembled detachable electronic device and an assembled detachable electronic device having the same.

2. Description of Related Art

In the modern information era, electronic products and daily life have become inseparable. As electronic technology continually develops, new electronic products that are user friendly with better functions have been replacing the old. For example, a tablet PC is convenient when being used. Further, the tablet PC may only require a desk or a lap to place on, and a stylus can be used to operate it. In order to further improve convenience and ease in operating tablet PCs, tablet PCs combined with electronic devices having docking stations with input interfaces (such as keyboard modules) have been developed.

Current docking stations mostly adopt a hinge structure so that when the tablet PC is assembled to the docking station it can be rotated relative to the docking station. However, the design of the hinge structure causes the thickness to increase when the tablet PC is assembled to the docking station. This does not satisfy the thin and light requirements in current electronic products. In order for the tablet PC to rotate open or close with respect to the docking station or have a suitable tilted angle, multiple hinge structures must be configured. This will increase the thickness when combining the tablet PC and the docking station, and will also increase production cost. Thus, the method of designing the docking stations of tablet PCs has room for improvement.

### SUMMARY OF THE INVENTION

The invention provides supporting assembly for an assembled detachable electronic device that can lower the thickness of a portable device combined to a docking station, further reducing cost.

The invention provides an assembled detachable electronic device, wherein a supporting assembly of the assembled detachable electronic device can lower the thickness of a portable device combined to a docking station, further reducing cost.

The invention provides supporting assembly for an assembled detachable electronic device, adapted to be assembled to a docking station main body of a docking station, and is adapted to be slidably disposed to a first sliding portion of a portable device having a display interface. The supporting assembly for the assembled detachable electronic device includes a flexbile element and a sliding element. The sliding element is wrapped by the flexible element. When the sliding element is slidably disposed to the first sliding portion, the flexible element provides a supporting force to support the portable device on the docking station main body. When the sliding element slides along the first sliding portion and the flexible element is bent, the portable device rotates relative to the docking station main body.

The invention provides an assembled detachable electronic device, including a portable device having a display interface and the aforementioned supporting assembly. The portable device includes at least one first sliding portion. When the sliding element of the supporting assembly is slidably disposed to the first sliding portion, the flexible element provides a supporting force to support the portable device on the docking station main body. When the sliding element slides along the first sliding portion and the flexible element is bent, the portable device rotates relative to the docking station main body.

In an embodiment of the invention, the supporting assembly includes a supporting element, wrapped by the flexible element, and is connected to the sliding element through the flexible element.

In an embodiment of the invention, in the assembled detachable electronic device, the portable device is adapted to close on the docking station main body as the sliding element slides along the first sliding portion and the flexible element bends.

In an embodiment of the invention, a tilting angle of the portable device of the assembled detachable electronic device is adapted to change as the sliding element slides along the first sliding portion and the flexible element bends.

In an embodiment of the invention, the first sliding portion of the portable device includes a blocking end. The blocking end restricts a sliding range of the sliding element along the first sliding portion.

In an embodiment of the invention, the sliding element includes a supporting portion and a second sliding portion. The portable device is adapted to lean against the supporting portion. The second sliding portion is adapted to be slidably disposed to the first sliding portion.

In an embodiment of the invention, an amount of the first sliding portions is two, and an amount of the second sliding portions is two. When the two second sliding portions are respectively slidably disposed to the two first sliding portions, the portable device is restricted to be between the two second sliding portions.

In an embodiment of the invention, the docking station main body includes a concave, and the second sliding portions are adapted to wedge in the concave.

In an embodiment of the invention, the docking station main body includes an input interface.

In an embodiment of the invention, the docking station main body includes a socket. The supporting assembly further includes an assembly element. The assembly element is disposed on the flexible element, and is inserted into the socket. This way, the supporting assembly is assembled to the docking station main body.

In an embodiment of the invention, the docking station main body further includes a locking element. The locking element locks the assembly element to the docking station main body.

Based on the above, the supporting assembly of the invention can support the portable device on the docking station main body. The portable device can rotate as the sliding element slides along the first sliding portion and the flexible element bends, so as to change the tilting angle or close onto the docking station main body. Since the portable device rotates through the bending of the flexible element, thus a hinge structure is not required to be disposed on the docking station. This reduces the thickness of the portable device combined with the docking station, and also reduces production cost. In addition, since the invention replaces a hinge structure with the flexible element to connect the docking station main body and the portable device, through the flexibility of the flexible element, the portable device can have more angles and positions for utilization.

Several exemplary embodiments accompanied with figures are described in detail below to further describe the disclosure in details.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIG. 1 is a three dimensional schematic diagram of an assembled detachable electronic device according to an embodiment of the invention.

FIG. 2 is a three dimensional schematic diagram of a portable device of FIG. 1 separated from a docking station.

FIG. 3 is a side schematic diagram of the assembled detachable electronic device of FIG. 1.

FIG. 4 is a partial cross-sectional view of the docking station of FIG. 1.

FIG. 5 is a three dimensional schematic diagram of the portable device of FIG. 1 at a different tilting angle.

FIG. 6 is a side schematic diagram of the assembled detachable electronic device of FIG. 5.

FIG. 7 is a partial cross-sectional view of the docking station of FIG. 5.

FIG. 8 is a three dimensional schematic diagram of the portable device of FIG. 1 closed onto a docking station main body.

FIG. 9 is a side schematic diagram of the assembled detachable electronic device of FIG. 8.

FIG. 10 is a partial cross-sectional view of the docking station of FIG. 8.

FIG. 11 is a three dimensional schematic diagram of a supporting assembly of the docking station of FIG. 1 fixed to the docking station main body.

### DESCRIPTION OF EMBODIMENTS

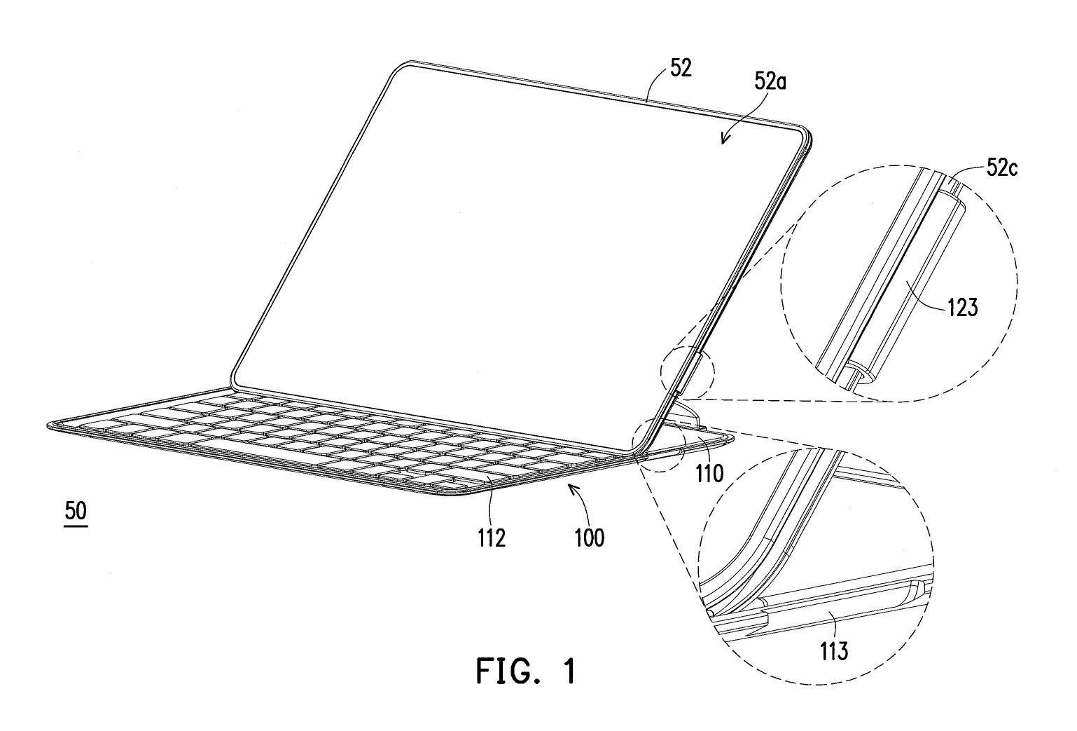

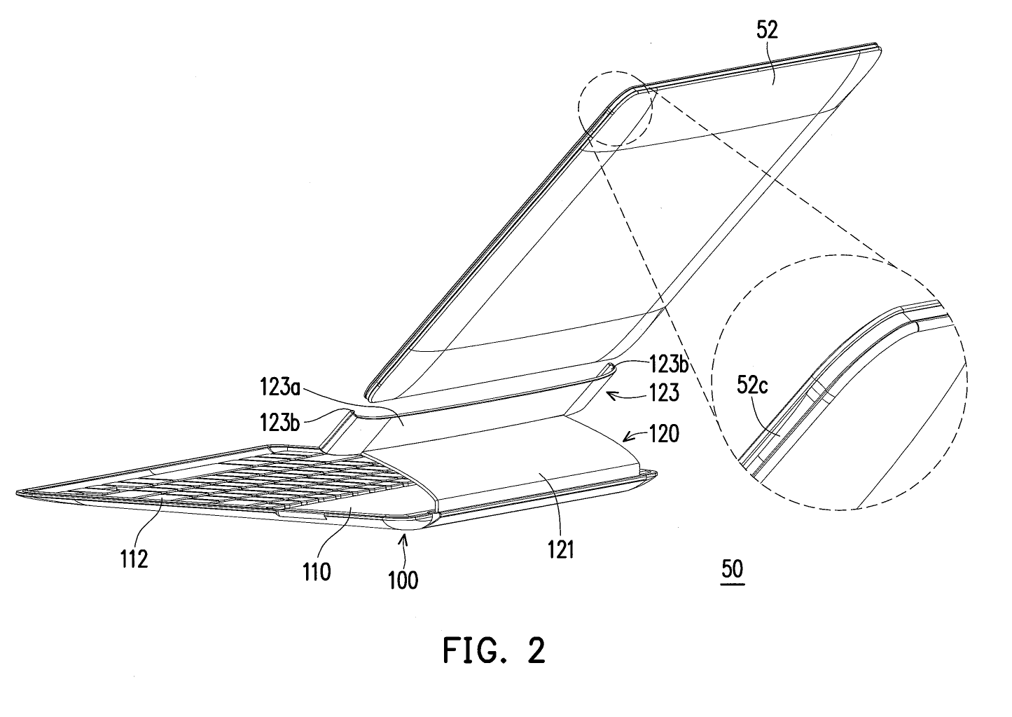

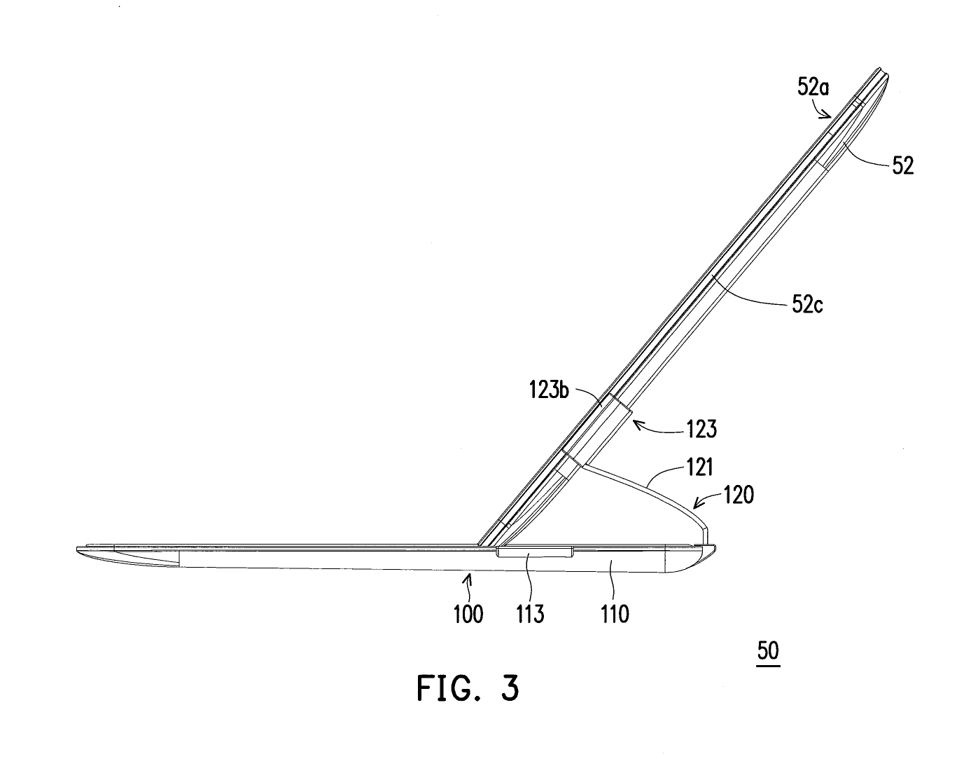

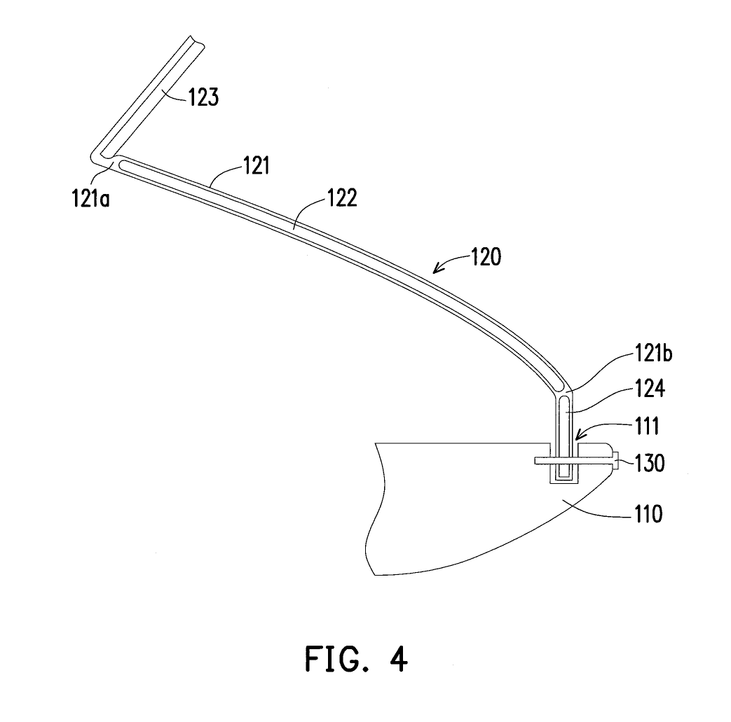

FIG. 1 is a three dimensional schematic diagram of an assembled detachable electronic device according to an embodiment of the invention. FIG. 2 is a three dimensional schematic diagram of a portable device of FIG. 1 separated from a docking station. FIG. 3 is a side schematic diagram of the assembled detachable electronic device of FIG. 1. FIG. 4 is a partial cross-sectional view of the docking station of FIG. 1. Please refer to FIG. 1 to FIG. 4. The assembled detachable electronic device 50 of the embodiment includes a portable device 52 and a docking station 100. The portable device 52 includes a display interface 52a and at least one first sliding portion 52c. The docking station 100 includes a docking station main body 110 and a supporting assembly 120 assembled to the docking station main body 110. The supporting assembly 120 includes a flexible element 121 and a sliding element 123. The sliding element 123 is wrapped by the flexible element 121. When the sliding element 123 is slidably disposed to the first sliding portion 52c, the flexible element 121 provides a supporting force to support the portable device 52 on the docking station main body 110. When the sliding element 123 slides along the first sliding portion 52c and the flexible element 121 is bent, the portable device 52 rotates relative to the docking station main body 110. The portable device 52 is for example, a tablet PC. The user can selectively use the portable device 52 with a handheld method, or by combining the portable device 52 with the docking station 100.

In detail, the supporting assembly 120 includes a supporting element 122. The supporting element 122 is wrapped by the flexible element 121. In the supporting assembly 120, the supporting element 122 is connected to the sliding element 123 through the flexible element 121. The supporting element 122 with the flexible element 121 can provide a suitable supporting force to support the portable device 52 when the portable device 52 is combined with the docking station 100.

When the user wants to combine the portable device 52 with the docking station 100, the sliding element 123 of the supporting assembly 120 is slidably disposed to the first sliding portion 52c of the portable device 52. When the sliding element 123 is slidably disposed to the first sliding portion 52c of the portable device 52, the sliding element 123 and the supporting element 122 can support the portable device 52 onto the docking station main body 110 of the docking station 100 as seen in FIG. 1 and FIG. 3.

The docking station main body 110 of the embodiment further includes an input interface 112 (such as a keyboard module). When the portable device 52 is combined with the docking station 100 as seen in FIG. 1, the display interface 52a faces the user and the input interface 112 is exposed. This allows the user to operate the input interface 112 and view the images displayed by the display interface 52a.

When the sliding element 123 slides along the first sliding portion 52c of the portable device 52 and the flexible element 121 is bent, the portable device 52 rotates relative to the docking station main body 110. Detailed explanations through figures are given below.

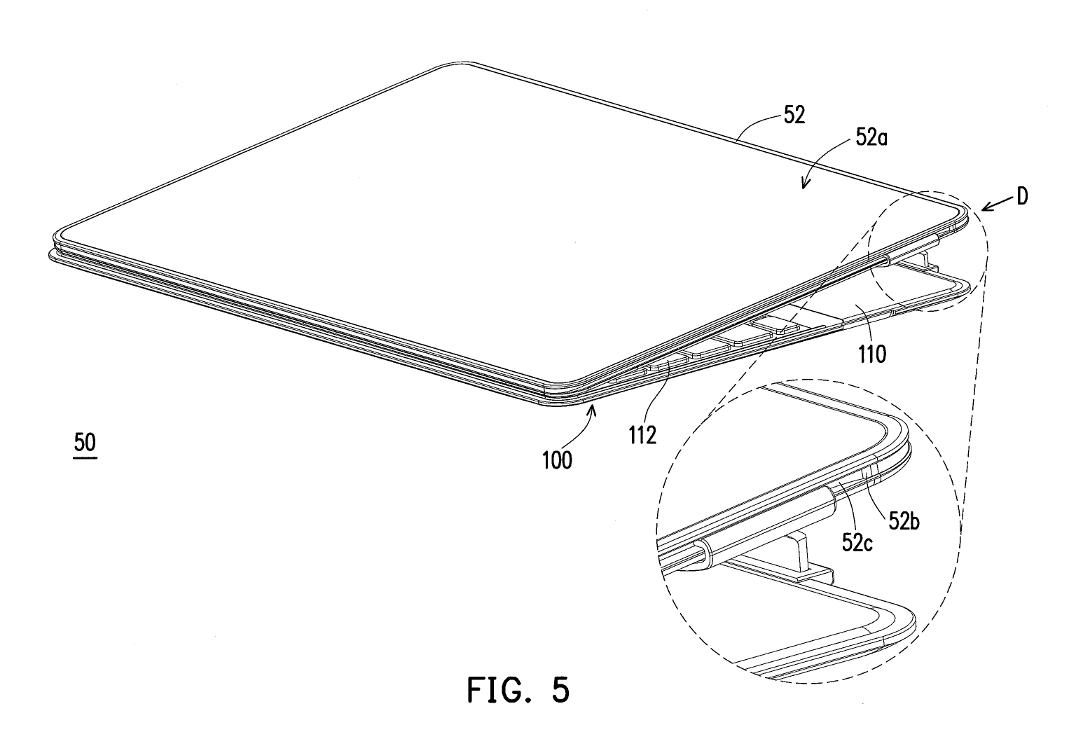

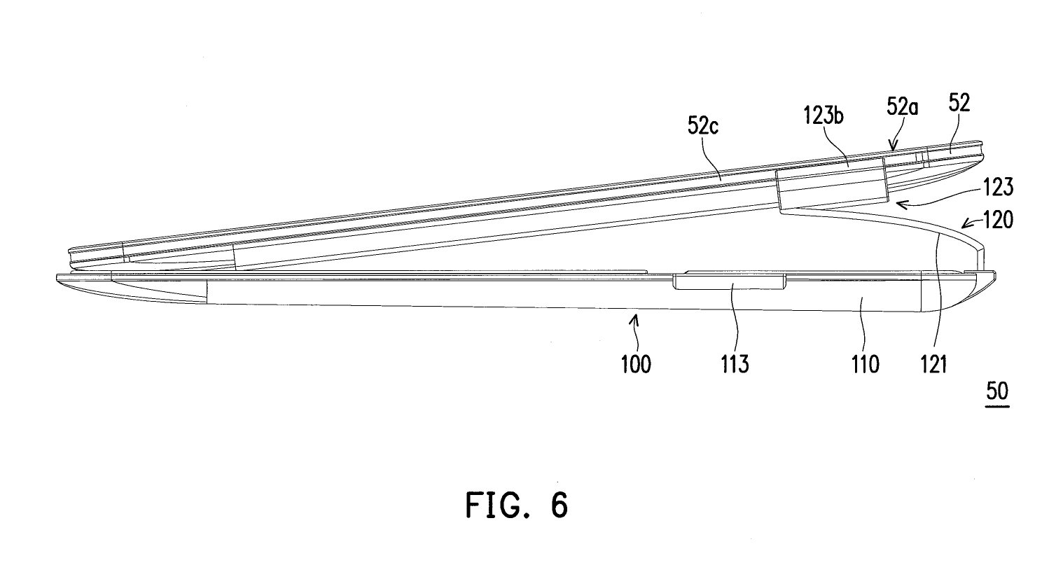

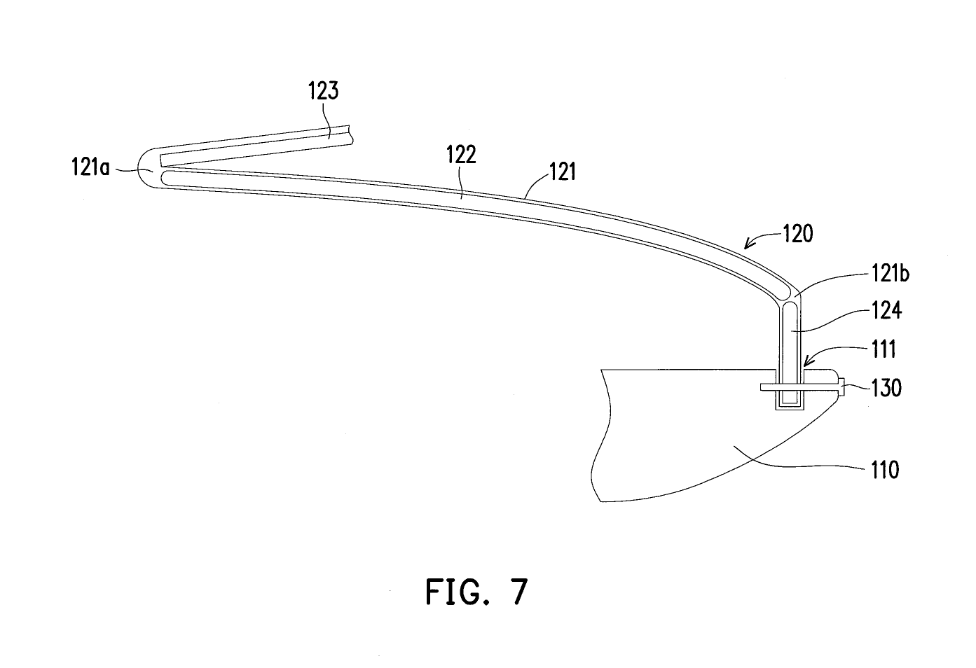

FIG. 5 is a three dimensional schematic diagram of the portable device of FIG. 1 at a different tilting angle. FIG. 6 is a side schematic diagram of the assembled detachable electronic device of FIG. 5. FIG. 7 is a partial cross-sectional view of the docking station of FIG. 5. When the flexible element 121 bends to the condition of FIG. 7, the tilting angle of the portable device 52 change from the condition of FIG. 1 and FIG. 3 to the condition of FIG. 5 and FIG. 6 as the sliding element 123 slides along the first sliding portion 52c and the flexible element 121 bends. At this point the display interface 52a of the potable device 52 is even more tilted, so that the user can conveniently operate the potable device 52 through a touch method.

As seen in FIG. 5, the first sliding portion 52c of the portable device 52 includes a blocking end 52b. The blocking end 52b restricts the sliding range of the sliding element 123 along the first sliding portion 52c. This way the portable device 52 can be stably disposed on the docking station main body 110.

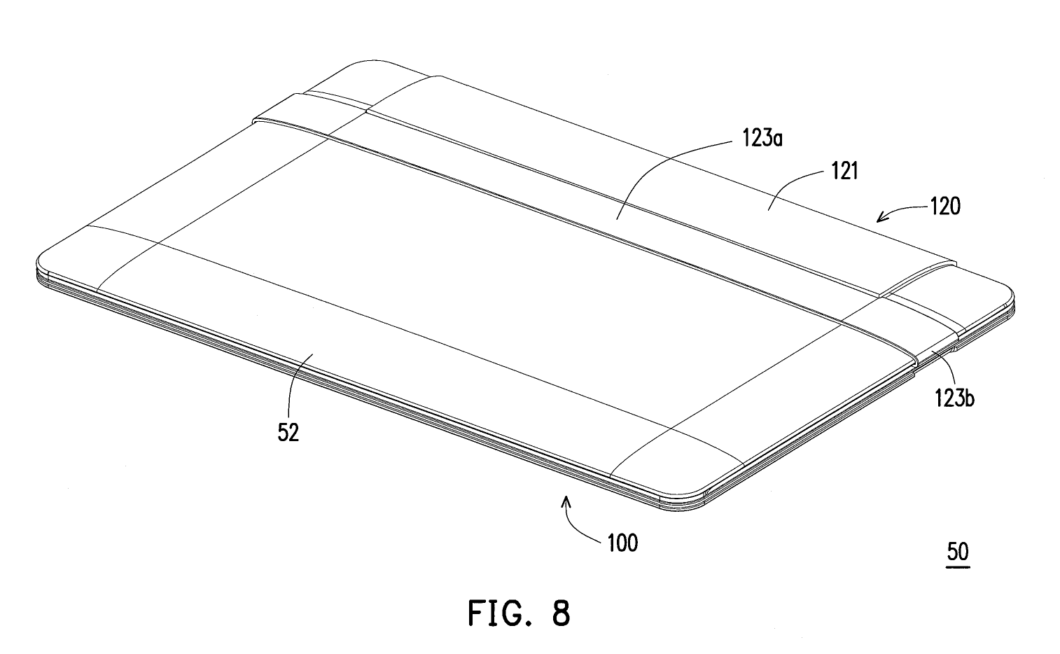

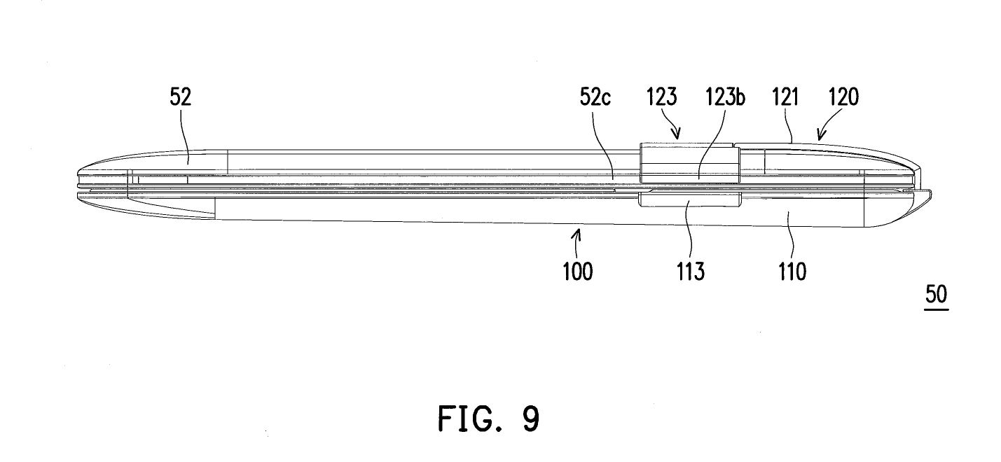

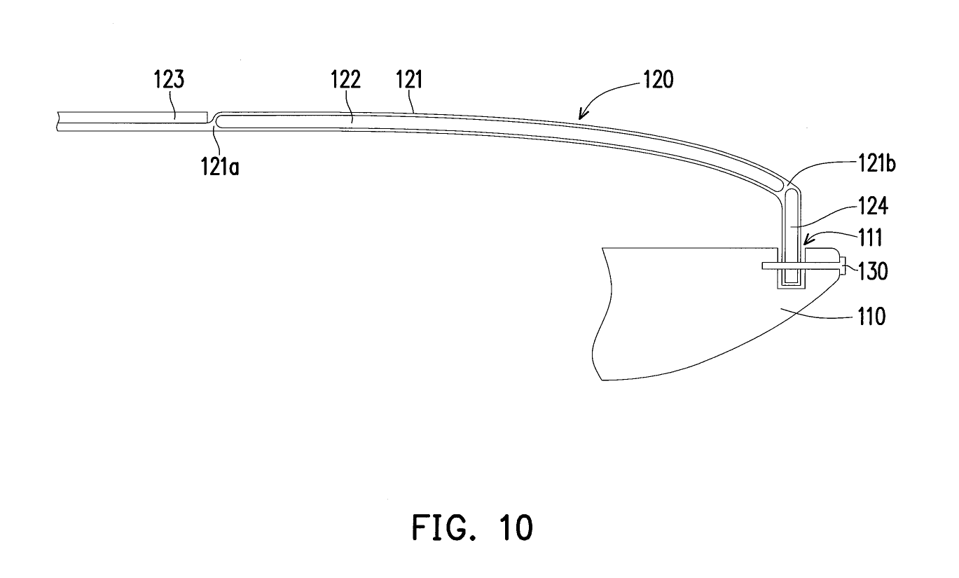

FIG. 8 is a three dimensional schematic diagram of the portable device of FIG. 1 closed onto a docking station main body. FIG. 9 is a side schematic diagram of the electronic device of FIG. 8. FIG. 10 is a partial cross-sectional view of the docking station of FIG. 8. When the user wants to store the assembled detachable electronic device 50 or carry the assembled detachable electronic device 50, the flexible element 121 can be bent to the condition as seen in FIG. 10. At this point, the portable device will close onto the docking station main body 110 as seen in FIG. 8 and FIG. 9, as the sliding element 123 slides along the first sliding portion 52c and the flexible element is bent 121. This condition is better for storage or for carrying around.

Under the aforementioned configuration, since the portable device 52 rotates through the bending of the flexible element 121, thus a hinge structure is not required to be disposed on the docking station 100. This reduces the thickness of the portable device 52 combined with the docking station 100, and also reduces production cost.

Referring to FIG. 10, in detail, the supporting element 122 of the embodiment is located between the sliding element 123 and an assembly element 124. A first flexible portion 121a of the flexible element 121 is located between the sliding element 123 and the supporting element 122, and can perform bending. A second flexible potion 121b of the flexible element 121 is located between the supporting element 122 and the assembly element 124, and can perform bending. The user can change the degree of bending in the first bending portion 121a and the second bending portion 121b to match the relative sliding between the sliding element 123 and the portable device 52. This way, the portable device 52 can be adjusted to the conditions shown in FIG. 1, FIG. 5, or FIG. 8.

Referring to FIG. 2, in detail, the sliding element 123 of the supporting assembly 120 of the embodiment further includes a supporting portion 123a and at least one second sliding element 123b. The portable electronic device 52 is adapted to lean against the supporting portion 123a, and the second sliding portion 123b is adapted to be slidably disposed to the first sliding portion 52c. In the embodiment, the amount of the first sliding portions 52c of the portable device 52 is two (FIG. 2 only shows one). The two first sliding portions 52c are respectively located on the two opposite sides of the portable device 52. The amount of the second sliding portions 123b of the sliding element 123 is two, and are respectively located on the two sides of the supporting portion 123a. The second sliding portions 123b are adapted to be respectively slidably disposed to the corresponding first sliding portions 52c of the portable device 52. When the two second sliding portions 123b are respectively slidably disposed to the two first sliding portions 52c, the portable device 52 is limited to be between the two second sliding portions 123b, so that the entire structure is more stable.

The portable device 52 and the supporting assembly 120 of the embodiment are slidably disposed to each other and can be separated. Thus, the portable device 52 is adapted to separate from the supporting assembly 120 so as to be detachable. This improves the variety in how the portable device 52 is used.

In the embodiment, the first sliding portion 52c is a sliding trench, and the second sliding portion 123b is a protrusion. However, the invention is not limited thereto. In another embodiment that is not drawn, the first sliding portion can be a protrusion, and the second sliding portion can be a corresponding sliding trench. In addition, in the embodiment, the amount of the first sliding portions 52c is two, and are respectively located on the two sides of the portable device 52. However, the invention is not limited thereto. In another embodiment that is not drawn, the first sliding portion can be disposed on a back cover of the portable device. The back cover is opposite to the display interface. The second sliding portion can be in a corresponding position to the first sliding portion, and is adapted to be slidably disposed to the first sliding portion. At this point the first sliding portion can be a sliding trench or a protrusion, and the second sliding portion can be a corresponding protrusion or a sliding trench.

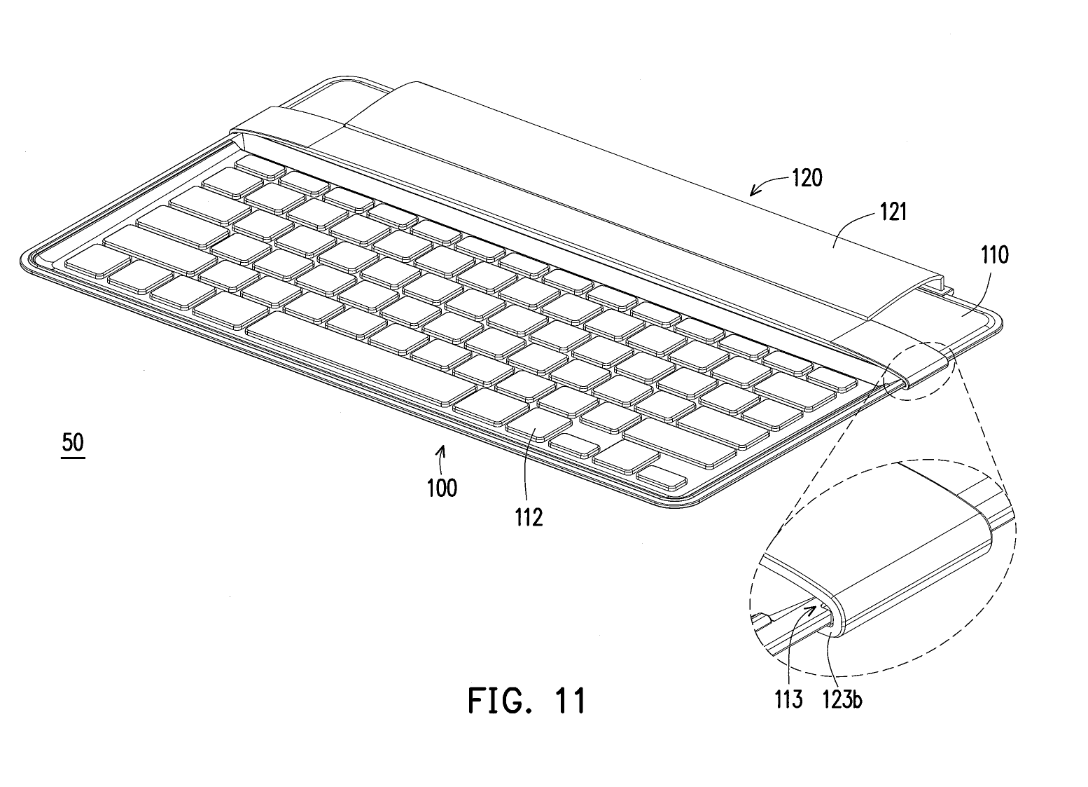

FIG. 11 is a three dimensional schematic diagram of a supporting assembly of FIG. 1 fixed to the docking station main body. Referring to both FIG. 1 and FIG. 11, the docking station main body 110 of the embodiment includes a concave 113. When the user wants to store or carry the docking station 100 by itself, the second sliding portion 123b of the sliding element 123 is wedged into the concave 113 of the docking station main body 110. This way, the supporting assembly 120 is fixed to the docking station main body 110, so it is easier to store or carry the docking station 100.

In addition, the second sliding portion 123b and the concave 113 can have a magnetic attraction. For example, a magnet can be adhered to the second sliding portion 123b, and a magnet can be adhered to the concave 113. When the second sliding portion 123b and the concave 113 have magnetism, the two can be attracted to each other through a magnetic force. In other embodiments, the second sliding portion 123b can select metal material that is attracted to magnets. When the concave 113 has magnetism, the second sliding portion 123b is attracted to the concave 113, so that the wedging relationship between the two is even more stable. The aforementioned magnetic components are, for example, permanent magnets or other suitable magnetic components.

Referring to FIG. 10, the docking station main body 110 of the embodiment includes a socket 111, and the supporting assembly 120 further includes an assembly element 124. The assembly element 124 is disposed on the flexible element 121, and is inserted into the socket 111. This way the supporting assembly 120 is assembled to the docking station main body 110. In detail, the docking station 100 of the embodiment further includes a locking element 130. The locking element 130 is, for example, a screw, adapted to lock the assembly element 124 and the docking station main body 110. This way, the supporting assembly 120 is stably assembled to the docking station main body 110.

In the embodiment, the materials of the assembly element 124 and the supporting element are plastic. The material of the sliding element 123 is metal. However, the invention is not limited thereto. The material of the flexible element 121 is leather. The assembly element 124 and the supporting element 122 is wrapped in the flexible element 121. This way, the supporting assembly 120 has a better external appearance. In other embodiments, the material of the flexible element 121 can be selected by other suitable flexible materials. The invention is not limited thereto.

To sum up, the supporting assembly of the invention can support the portable device on the docking station main body. The portable device can rotate as the sliding element slides along the first sliding portion and the flexible element bends, so as to change the tilting angle or close onto the docking station main body. Since the portable device rotates through the bending of the flexible element, thus a hinge structure is not required to be disposed on the docking station. This reduces the thickness of the portable device combined with the docking station, and also reduces production cost. In addition, since the invention replaces a hinge structure with the flexible element to connect the docking station main body and the portable device, through the flexibility of the flexible element, the portable device can have more angles and positions for utilization. In addition, the portable device and the supporting assembly are slidably disposed to each other and can be separated. Thus, the portable device is adapted to separate from the supporting assembly so as to be detachable. This improves the variety in how the portable device is used.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. An assembled detachable electronic device, comprising:
a portable device with a display interface, having at least one first sliding portion; and
a docking station, comprising:
a docking station main body; and
a supporting assembly, assembled to the docking station main body so as to support the portable device, comprising:
a flexible element; and
a sliding element, wrapped by the flexible element, wherein when the sliding element is slidably disposed to the first sliding portion, the flexible element provides a supporting force to support the portable device on the docking station main body, and when the sliding element slides along the first sliding portion and the flexible element is bent, the portable device rotates relative to the docking station main body.

2. The assembled detachable electronic device as claimed in claim 1, wherein the supporting assembly includes a supporting element, wrapped by the flexible element, wherein the supporting element is connected to the sliding portion through the flexible element.

3. The assembled detachable electronic device as claimed in claim 1, wherein the portable device is adapted to close on the docking station main body as the sliding element slides along the first sliding portion and the flexible element bends.

4. The assembled detachable electronic device as claimed in claim 1, wherein a tilting angle of the portable device is adapted to change as the sliding element slides along the first sliding portion and the flexible element bends.

5. The assembled detachable electronic device as claimed in claim 1, wherein the first sliding portion of the portable device includes a blocking end, and the blocking end restricts a sliding range of the sliding element along the first sliding portion.

6. The assembled detachable electronic device as claimed in claim 1, wherein the sliding element comprises:
a supporting portion, wherein the portable device is adapted to lean against the supporting portion; and
at least one second sliding portion, adapted to be slidably disposed to the first sliding portion.

7. The assembled detachable electronic device as claimed in claim 6, wherein an amount of the at least one first sliding portion is two, and an amount of the at least one second sliding portion is two, wherein when the two second sliding portions are respectively slidably disposed to the two first sliding portions, the portable device is restricted to be between the two second sliding portions.

8. The assembled detachable electronic device as claimed in claim 6, wherein the docking station main body includes a concave, and the second sliding portions are adapted to be wedged into the concave.

9. The assembled detachable electronic device as claimed in claim 1, wherein the docking station main body includes an input interface.

10. The assembled detachable electronic device as claimed in claim 1, wherein the docking station main body includes a socket, and the supporting assembly further includes an assembly element, wherein the assembly element is disposed on the flexible element, and is inserted into the socket, so that the supporting assembly is assembled to the docking station main body.

11. The assembled detachable electronic device as claimed in claim 10, wherein the docking station main body includes a locking element, and the locking element locks the assembly element to the docking station main body.

12. A supporting assembly for an assembled detachable electronic device, adapted to be assembled to a docking station main body of a docking station, and is adapted to be slidably disposed to at least one first sliding portion of a portable device, the supporting assembly for an assembled detachable electronic device comprising:
a flexible element; and
a sliding element, wrapped by the flexible element, wherein when the sliding element is slidably disposed to the first sliding portion, the flexible element provides a supporting force to support the portable device on the docking station main body, and when the sliding element slides along the first sliding portion and the flexible element is bent, the portable device rotates relative to the docking station main body.

13. The supporting assembly for the assembled detachable electronic device as claimed in claim 12, comprising a supporting element, wrapped by the flexible element, wherein the supporting element is connected to the sliding portion through the flexible element.

14. The supporting assembly for the assembled detachable electronic device as claimed in claim 12, wherein the portable device is adapted to close on the docking station main body as the sliding element slides along the first sliding portion and the flexible element bends.

15. The supporting assembly for the assembled detachable electronic device as claimed in claim 12, wherein a tilting angle of the portable device is adapted to change as the sliding element slides along the first sliding portion and the flexible element bends.

16. The supporting assembly for the assembled detachable electronic device as claimed in claim 12, wherein the first sliding portion of the portable device includes a blocking end, and the blocking end restricts a sliding range of the sliding element along the first sliding portion.

17. The supporting assembly for the assembled detachable electronic device as claimed in claim 12, wherein the sliding element comprises:
a supporting portion, wherein the portable device is adapted to lean against the supporting portion; and
at least one second sliding portion, adapted to be slidably disposed to the first sliding portion.

18. The supporting assembly for the assembled detachable electronic device as claimed in claim 17, wherein an amount of the at least one first sliding portion is two, and an amount of the at least one second sliding portion is two, wherein when the two second sliding portions are respectively slidably disposed to the two first sliding portions, the portable device is restricted to be between the two second sliding portions.

19. The supporting assembly for the assembled detachable electronic device as claimed in claim 17, wherein the docking station main body includes a concave, and the second sliding portions are adapted to be wedged into the concave.

20. The supporting assembly for the assembled detachable electronic device as claimed in claim 12, wherein the docking station main body includes an input interface.

21. The supporting assembly for the assembled detachable electronic device as claimed in claim 12, wherein the docking station main body includes a socket, and the supporting assembly further includes an assembly element, wherein the assembly element is disposed on the flexible element, and is inserted into the socket, so that the supporting assembly is assembled to the docking station main body.

22. The supporting assembly for the assembled detachable electronic device as claimed in claim 21, wherein the docking station main body includes a locking element, and the locking element locks the assembly element to the docking station main body.
